(19) United States
(12) Patent Application Publication
(10) Pub. No.: US 2025/0294842 A1
(43) Pub. Date: Sep. 18, 2025

(54) SEMICONDUCTOR DEVICE

(71) Applicant: SUMITOMO ELECTRIC INDUSTRIES, LTD., Osaka (JP)

(72) Inventor: Shigeki YOSHIDA, Osaka (JP)

(21) Appl. No.: 19/071,137

(22) Filed: Mar. 5, 2025

(30) Foreign Application Priority Data
Mar. 13, 2024 (JP) 2024-038526

(51) Int. Cl. H10D 62/854; H10D 30/01; H10D 30/47; H10D 62/60; H10D 62/824; H10D 62/85; H10D 62/852

(52) U.S. Cl. CPC H10D 62/854; H10D 30/475; H10D 62/60; H10D 30/015; H10D 62/824; H10D 62/8503; H10D 62/852

(57) ABSTRACT

A semiconductor device includes a buffer layer including iron and having a nitrogen polarity at an upper surface thereof, a barrier layer provided on the buffer layer and having a nitrogen polarity at an upper surface thereof, and a channel layer provided on the barrier layer and having a nitrogen polarity at an upper surface thereof.

### CROSS-REFERENCE TO RELATED APPLICATIONS

This application is based upon and claims priority to Japanese Patent Application No. 2024-038526, filed on Mar. 13, 2024, the entire contents of which are incorporated herein by reference.

### TECHNICAL FIELD

The present disclosure relates to semiconductor devices.

### BACKGROUND

Conventionally, there is a proposed high electron mobility transistor (HEMT) nitride semiconductor using a nitride semiconductor.

Related art includes International Publication Pamphlet No. WO 2017/002317.

In recent years, an amount of heat generated from a semiconductor device increased due to improvements in an operating speed of the semiconductor device, and there are increased demands to improve heat dissipation.

### SUMMARY

A semiconductor device of according to an aspect of the present disclosure includes a buffer layer including iron and having a nitrogen polarity at an upper surface thereof; a barrier layer provided on the buffer layer and having a nitrogen polarity at an upper surface thereof; and a channel layer provided on the barrier layer and having a nitrogen polarity at an upper surface thereof.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view illustrating a semiconductor device according to an embodiment;

FIG. 2 is a sectional view (part 1) illustrating a method for manufacturing the semiconductor device according to the embodiment;

FIG. 3 is a cross sectional view (part 2) illustrating the method for manufacturing the semiconductor device according to the embodiment;

FIG. 4 is a sectional view (part 3) illustrating the method for manufacturing the semiconductor device according to the embodiment;

FIG. 5 is a sectional view (part 4) illustrating the method for manufacturing the semiconductor device according to the embodiment;

FIG. 6 is a cross sectional view (part 5) illustrating the method for manufacturing the semiconductor device according to the embodiment;

FIG. 7 is a sectional view (part 6) illustrating the method for manufacturing the semiconductor device according to the embodiment;

FIG. 8 is a cross sectional view illustrating the semiconductor device according to a modification of the embodiment; and

FIG. 9 is a diagram illustrating a relationship between a polarity of an upper surface of a nitride semiconductor layer and a distribution of a Fe atom concentration.

### DETAILED DESCRIPTION

### Description of Embodiments of the Present Disclosure

One object according to an aspect of the present disclosure is to provide a semiconductor device capable of improving heat dissipation.

First, embodiments of the present disclosure will be described with reference to the drawings.

[1] According to a first aspect of the present disclosure, a semiconductor device includes a buffer layer including iron and having a nitrogen (N) polarity at an upper surface thereof, a barrier layer provided on the buffer layer and having a nitrogen polarity at an upper surface thereof, and a channel layer provided on the barrier layer and having a nitrogen polarity at an upper surface thereof.

Because the buffer layer includes iron as a dopant, the buffer layer can be made to have a high resistance, and thus, a high output power and high frequency characteristics can easily be obtained. The present inventor also found that, in a case where the upper surface of the buffer layer, the upper surface of the barrier layer, and the upper surface of the channel layer have the nitrogen (N) polarity, iron atoms doped in the buffer layer are less likely to diffuse from the buffer layer to the channel layer when compared to a case where the upper surfaces have a gallium (Ga) polarity. The iron atoms in the channel layer deteriorate an electron mobility of a two-dimensional electron gas (2DEG) in the channel layer. Mostly, iron is not doped in the buffer layer. Further, in this semiconductor device, because the upper surface of the buffer layer, the upper surface of the barrier layer, and the upper surface of the channel layer have the nitrogen polarity, the diffusion of iron atoms from the buffer layer to the channel layer and a decrease in the electron mobility caused by the iron atoms in the channel layer are unlikely to occur. This semiconductor device generates heat when electrons move in the channel layer. Accordingly, by reducing a distance between the buffer layer and the channel layer, it is possible to improve heat dissipation (thermal conduction) from the channel layer to a substrate while obtaining a high electron mobility.

[2] According to a second aspect of the present disclosure, in the semiconductor device of [1] above, the barrier layer may have a thickness greater than or equal to 1 nm and smaller than or equal to 50 nm. When the barrier layer has the thickness greater than or equal to 1 nm and smaller than or equal to 50 nm, the thermal conduction can easily be improved, while the electron mobility is unlikely to decrease and the iron atoms are unlikely to diffuse from the buffer layer to the channel layer.

[3] According to a third aspect of the present disclosure, in the semiconductor device of [1] above, a gap (separation) between the upper surface of the buffer layer and a lower surface of the channel layer may be greater than or equal to 1 nm and less than or equal to 50 nm. When the separation between the upper surface of the buffer layer and the lower surface of the channel layer is greater than or equal to 1 nm and less than or equal to 50 nm, the thermal conduction along a normal direction described later can easily be improved, while the electron mobility is unlikely to decrease and the iron atoms are unlikely to diffuse to the channel layer.

[4] According to a fourth aspect, in the semiconductor device of any one of [1] to [3] above, an average value of a concentration of iron atoms in the channel layer may be 2×10¹⁶ cm⁻³ or lower. When the average value of the concentration of the iron atoms in the channel layer is 2×10¹⁶ cm⁻³ or lower, a high electron mobility can easily be obtained in a channel region.

[5] According to a fifth aspect of the present disclosure, in the semiconductor device of any one of [1] to [4] above, an average value of a concentration of iron atoms in the buffer layer may be 5×10¹⁷ cm⁻³ or higher. When the average value of the concentration of the iron atoms in the buffer layer is 5×10¹⁷ cm⁻³ or higher, the buffer layer can have a high resistance.

[6] According to a sixth aspect of the present disclosure, in the semiconductor device of [1] above, a thickness of the barrier layer may be greater than or equal to 1 nm and less than or equal to 50 nm, an average value of a concentration of iron atoms in the channel layer may be 2×10¹⁶ cm⁻³ or lower, and an average value of a concentration of iron atoms in the buffer layer may be 5×10¹⁷ cm⁻³ or higher. When the barrier layer has the thickness greater than or equal to 1 nm and less than or equal to 50 nm, the thermal conduction from the channel layer to the substrate can easily be improved, while the electron mobility is unlikely to decrease and the iron atoms are unlikely to diffuse from the buffer layer to the channel layer. When the average value of the concentration of the iron atoms in the channel layer is 2×10¹⁶ cm⁻³ or lower, a high electron mobility can easily obtained in a channel region. When the average value of the concentration of the iron atoms in the buffer layer is 5×10¹⁷ cm⁻³ or higher, the buffer layer can have a high resistance.

[7] According to a seventh aspect of the present disclosure, in the semiconductor device of any one of [1] to [6] above, the buffer layer may be a gallium nitride layer, the barrier layer may be an aluminum gallium nitride layer, and the channel layer may be a gallium nitride layer. In this case, it is possible to stably form the buffer layer, the barrier layer, and the channel layer with ease.

### Details of Embodiments of the Present Disclosure

Hereinafter, embodiments of the present disclosure will be described in detail, but the present disclosure is not limited thereto. In the present specification and the drawings, constituent elements or components having substantially the same functional configuration are designated by the same reference numerals, and a redundant description thereof may be omitted. In the present disclosure, “a plan view” of a constituent element or component refers to a view from above the constituent element or component. More particularly, the plan view of a substrate, for example, refers to a view from above the substrate in a normal direction to a substrate surface.

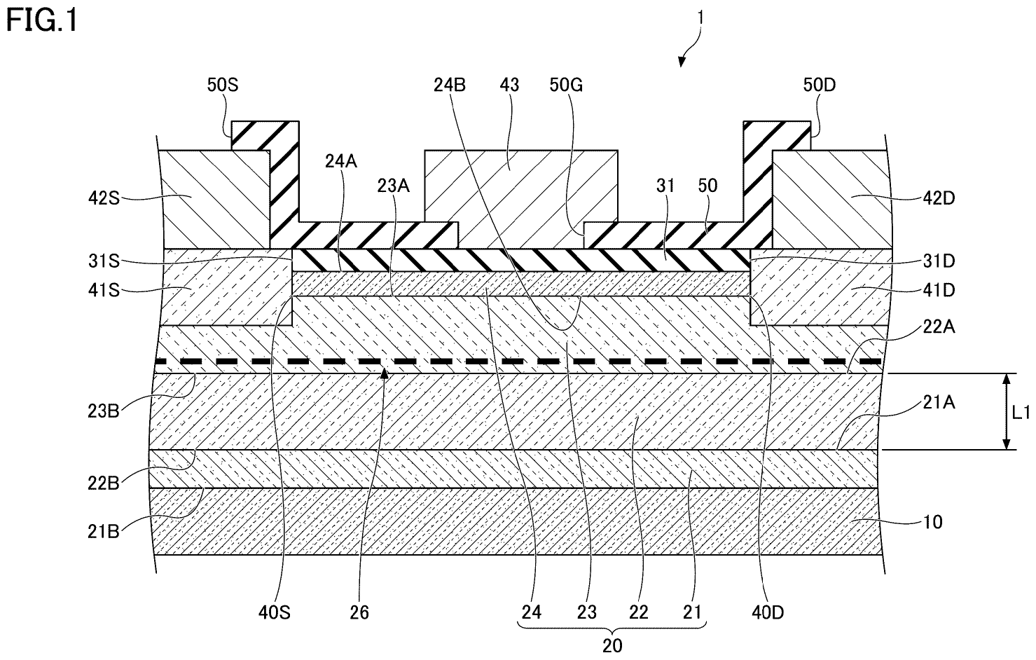

An embodiment relates to a semiconductor device including a GaN-based high electron mobility transistor (HEMT). FIG. 1 is a cross sectional view illustrating the semiconductor device according to the embodiment.

As illustrated in FIG. 1, a semiconductor device 1 according to the embodiment mainly includes a substrate 10, a nitride semiconductor layer 20, a dielectric film 31, a passivation film 50, a regrowth layer 41S, a regrowth layer 41D, a gate electrode 43, a source electrode 42S, and a drain electrode 42D.

The substrate 10 is a semi-insulating silicon carbide (SiC) substrate, for example. In the case where the substrate 10 is a SiC substrate, an upper surface of the substrate 10 is a carbon (C) polar face. In the case where the upper surface of the substrate 10 is a C polar face, the nitride semiconductor layer 20 can be grown thereon by causing crystal growth using a nitrogen (N) polar face as a growth surface.

The nitride semiconductor layer 20 includes a buffer layer 21, a barrier layer 22, a channel layer 23, and a cap layer 24. The nitride semiconductor layer 20 may include a nucleation layer between the substrate 10 and the buffer layer 21.

The buffer layer 21 is provided on the substrate 10. The buffer layer 21 includes iron (Fe) atoms. The iron is doped in the buffer layer 21 as a dopant. The buffer layer 21 is a gallium nitride (GaN) layer including iron (Fe), for example. Namely, the buffer layer 21 is an iron-doped GaN layer. The buffer layer 21 has a thickness greater than or equal to 10 nm and less than or equal to 1000 nm, for example. For example, the buffer layer 21 has a resistivity of 1 MΩ·m or higher.

The barrier layer 22 is provided on the buffer layer 21. The barrier layer 22 is an aluminum gallium nitride (AlGaN) layer, for example. A band gap of the barrier layer 22 is larger than a band gap of the channel layer 23. The barrier layer 22 has a thickness greater than or equal to 1 nm and less than or equal to 50 nm, for example. The barrier layer 22 has a composition Al_{Y}Ga_{1-Y}N (0.15<=Y<=0.55), for example. A conductivity type of the barrier layer 22 is the n-type or undoped (i-type), for example. Even if iron is not doped in the barrier layer 22, the barrier layer 22 may include Fe atoms diffused from the iron-doped buffer layer 21. Instead of using the AlGaN layer, the barrier layer 22 may use a scandium aluminum nitride (ScAlN) layer, an indium aluminum nitride (InAlN) layer, or an indium aluminum gallium nitride (InAlGaN) layer. In the case where the barrier layer 22 has the composition Al_{Y}Ga_{1-Y}N, a ratio of Al in group III elements of the barrier layer 22 is Y×100%.

The channel layer 23 is provided on the barrier layer 22. The channel layer 23 is a GaN layer, for example. The band gap of the channel layer 23 is smaller than the band gap of the barrier layer 22. The channel layer 23 has a thickness greater than or equal to 1 nm and less than or equal to 50 nm, for example. Strain is generated between the channel layer 23 and the barrier layer 22 due to a difference between lattice constants thereof, and this strain induces a piezoelectric charge at an interface between the channel layer 23 and the barrier layer 22. As a result, a two-dimensional electron gas (2DEG) is generated in the channel layer 23 in a vicinity of the surface facing the barrier layer 22, thereby forming a channel region 26. A conductivity type of the channel layer 23 is the n-type or undoped (i-type), for example. Mostly, iron is not doped in the channel layer 23. Even in such case, the channel layer 23 may include Fe atoms diffused from the buffer layer 21 through the barrier layer 22. An average value of the concentration of the Fe atoms in the channel layer 23 is smaller than an average value of the concentration of the Fe atoms in the barrier layer 22, and the average value of the concentration of the Fe atoms in the barrier layer 22 is smaller than an average value of the concentration of the Fe atoms in the buffer layer 21.

The cap layer 24 is provided on the channel layer 23. The cap layer 24 is an AlGaN layer, for example. The cap layer 24 has a thickness greater than or equal to 0.2 nm and less than or equal to 10 nm, for example.

The buffer layer 21, the barrier layer 22, the channel layer 23, and the cap layer 24 are grown by causing crystal growth using the N polar faces as growth surfaces, on the C polar face of the SiC substrate 10. Hence, upper surfaces 21A, 22A, 23A, and 24A of the buffer layer 21, the barrier layer 22, the channel layer 23, and the cap layer 24 have a nitrogen (N) polarity. On the other hand, lower surfaces 21B, 22B, 23B, and 24B of the buffer layer 21, the barrier layer 22, the channel layer 23, and the cap layer 24 have a gallium (Ga) polarity or an aluminum (Al) polarity.

A recess 40S for a source and a recess 40D for a drain are formed in the nitride semiconductor layer 20. A bottom of the recess 40S and a bottom of the recess 40D are closer to the lower surface 23B of the channel layer 23 than to the upper surface 23A of the channel layer 23. That is, the recess 40S and the recess 40D are formed to a depth deeper than the upper surface 23A of the channel layer 23. The bottom of the recess 40S and the bottom of the recess 40D may be located in the channel layer 23 or in the barrier layer 22.

The dielectric film 31 is provided on the nitride semiconductor layer 20. The dielectric film 31 is in contact with the upper surface 24A of the cap layer 24. For example, a dielectric constant of the dielectric film 31 is higher than a dielectric constant of silicon dioxide (SiO₂). The dielectric film 31 may be a high dielectric constant film. The dielectric film 31 is a silicon nitride (SiN) film, for example. The dielectric film 31 may be a dielectric oxide film or a dielectric oxynitride film. The dielectric oxide film or the dielectric oxynitride film may include at least one element selected from a group consisting of hafnium (Hf), lanthanum (La), and zirconium (Zr). In addition, the dielectric oxide film or the dielectric oxynitride film may include at least one element selected from a group consisting of silicon (Si) and aluminum (Al). For example, the dielectric film 31 may be a hafnium silicate (HfSiOₓ) film, a hafnium aluminate (HfAlOₓ) film, a hafnium silicon oxynitride (HfSiON) film, or a hafnium aluminum oxynitride (HfAlON) film. The dielectric film 31 has a thickness greater than or equal to 1 nm and less than or equal to 30 nm, for example. An opening 31S for the source and an opening 31D for the drain are formed in the dielectric film 31. The opening 31S is connected to the recess 40S, and the opening 31D is connected to the recess 40D.

The regrowth layer 41S is provided on the channel layer 23 or the barrier layer 22 inside the recess 40S. The regrowth layer 41D is provided on the channel layer 23 or the barrier layer 22 inside the recess 40D. The regrowth layer 41S and the regrowth layer 41D are n-type GaN layers, for example. The regrowth layer 41S and the regrowth layer 41D include germanium (Ge) or silicon (Si) as an n-type impurity. Electrical resistances of the regrowth layer 41S and the regrowth layer 41D are lower than an electrical resistance of the channel layer 23. For example, the regrowth layer 41S and the regrowth layer 41D are formed by regrowth of the n-type GaN layer after the formation of the recess 40S and the recess 40D in the nitride semiconductor layer 20.

The source electrode 42S is provided on the regrowth layer 41S, and the drain electrode 42D is provided on the regrowth layer 41D. The source electrode 42S is in contact with the regrowth layer 41S, and the drain electrode 42D is in contact with the regrowth layer 41D. The source electrode 42S make ohmic contact with the regrowth layer 41S, and the drain electrodes 42D makes ohmic contact with the regrowth layer 41D.

The passivation film 50 covers the dielectric film 31, the regrowth layer 41S, the regrowth layer 41D, the source electrode 42S, and the drain electrode 42D. The passivation film 50 is a SiN film, for example. The passivation film 50 has a thickness greater than or equal to 5 nm and less than or equal to 50 nm, for example, in a portion on the dielectric film 31 where the passivation film 50 has a uniform thickness. An opening 50S for the source, an opening 50D for the drain, and an opening 50G for the gate are formed in the passivation film 50. The opening 50S reaches the source electrode 42S, and the opening 50D reaches the drain electrode 42D. In the plan view, the opening 50G is located between the opening 50S and the opening 50D. The opening 50G reaches the dielectric film 31.

In the plan view, the gate electrode 43 is located between the source electrode 42S and the drain electrode 42D. The gate electrode 43 is provided on the passivation film 50 and the dielectric film 31, and is in contact with the dielectric film 31 through the opening 50G.

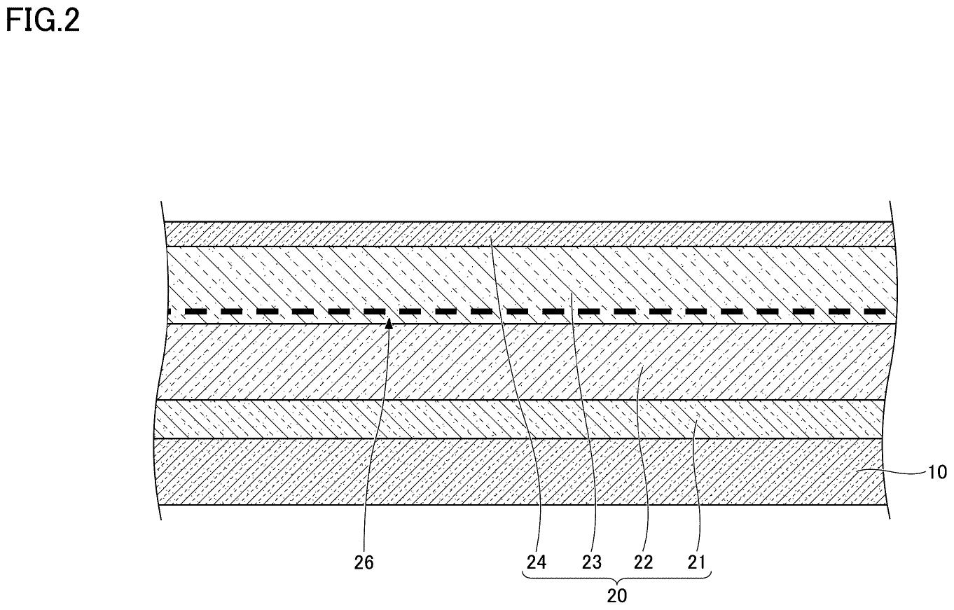

Next, a method for manufacturing the semiconductor device 1 according to the embodiment will be described. FIG. 2 through FIG. 7 are cross sectional views illustrating the method for manufacturing the semiconductor device 1 according to the embodiment.

First, as illustrated in FIG. 2, the nitride semiconductor layer 20 is formed on the substrate 10 by metal organic chemical vapor deposition (MOCVD), for example. When forming the nitride semiconductor layer 20, the buffer layer 21, the barrier layer 22, the channel layer 23, and the cap layer 24 are formed in this order. In the forming processes, iron is doped in the buffer layer 21, but not doped in the barrier layer 22 and the channel layer 23

When forming the buffer layer 21, a temperature inside a chamber is set higher than or equal to 1000° C. and lower than or equal to 1100° C., a pressure inside the chamber is set higher than or equal to 10 kPa and lower than or equal to 15 kPa, and a V/III ratio is set greater than or equal to 1000 and less than or equal to 1100. The V/III ratio refers to a ratio of a supply rate (moles) of a V group element per unit time with respect to a supply rate (moles) of a III group element per unit time.

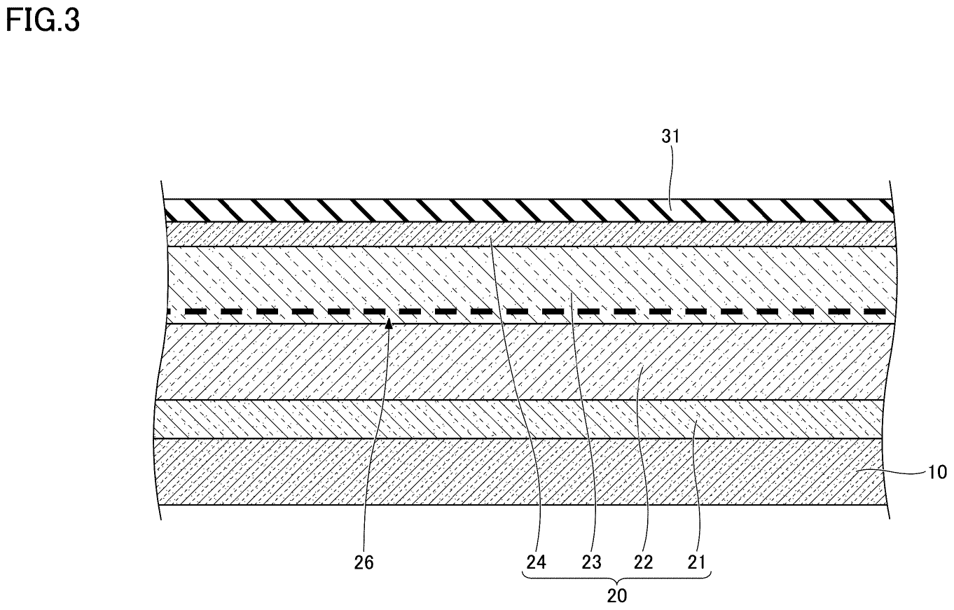

Next, as illustrated in FIG. 3, the dielectric film 31 is formed on the nitride semiconductor layer 20.

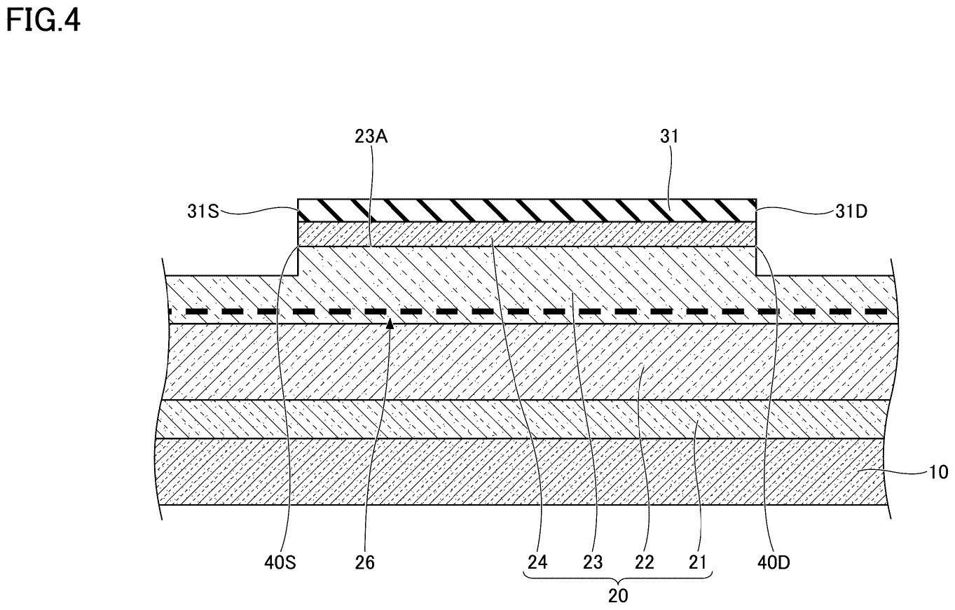

Next, as illustrated in FIG. 4, the opening 31S for the source and the opening 31D for the drain are formed in the dielectric film 31, and the recess 40S for the source and the recess 40D for the drain are formed in the nitride semiconductor layer 20. The bottom of the recess 40S and the bottom of the recess 40D may be closer to the lower surface of the nitride semiconductor layer 20 than to the upper surface 23A of the channel layer 23. That is, the recess 40S and the recess 40D may be formed to the depth deeper than the upper surface 23A of the channel layer 23. The bottom of the recess 40S and the bottom of the recess 40D may be located in the channel layer 23 or in the barrier layer 22. The opening 31S, the opening 31D, the recess 40S, and the recess 40D can be formed by reactive ion etching (RIE) using a mask (not illustrated), for example.

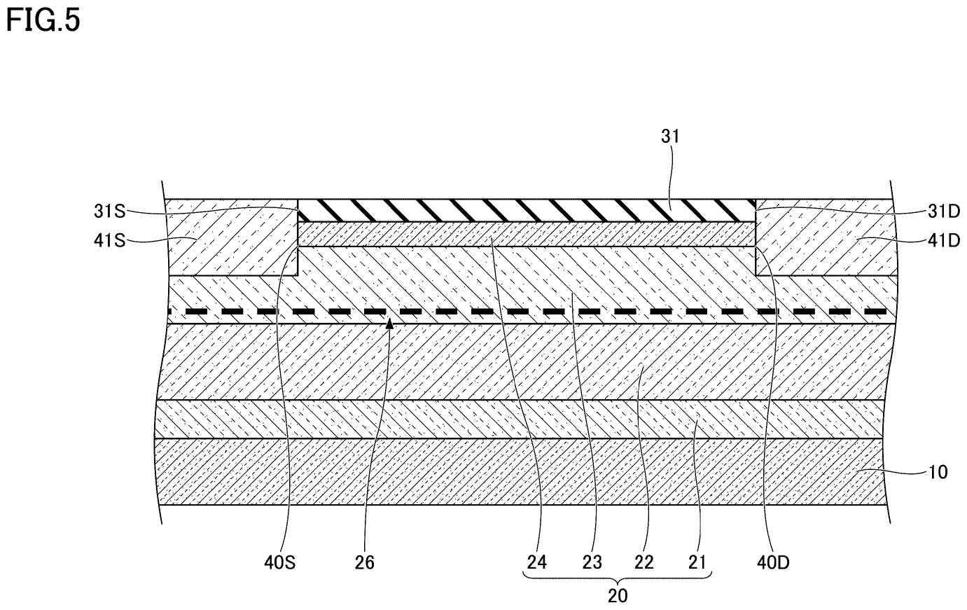

Next, as illustrated in FIG. 5, the regrowth layer 41S is formed on the channel layer 23 or the barrier layer 22 inside the recess 40S, and the regrowth layer 41D is formed on the channel layer 23 or the barrier layer 22 inside the recess 40D. The regrowth layer 41S and the regrowth layer 41D can be formed by physical vapor deposition (PVD), such as vapor deposition, sputtering, molecular beam epitaxy (MBE), or the like, or by metal organic chemical vapor deposition (MOCVD), for example.

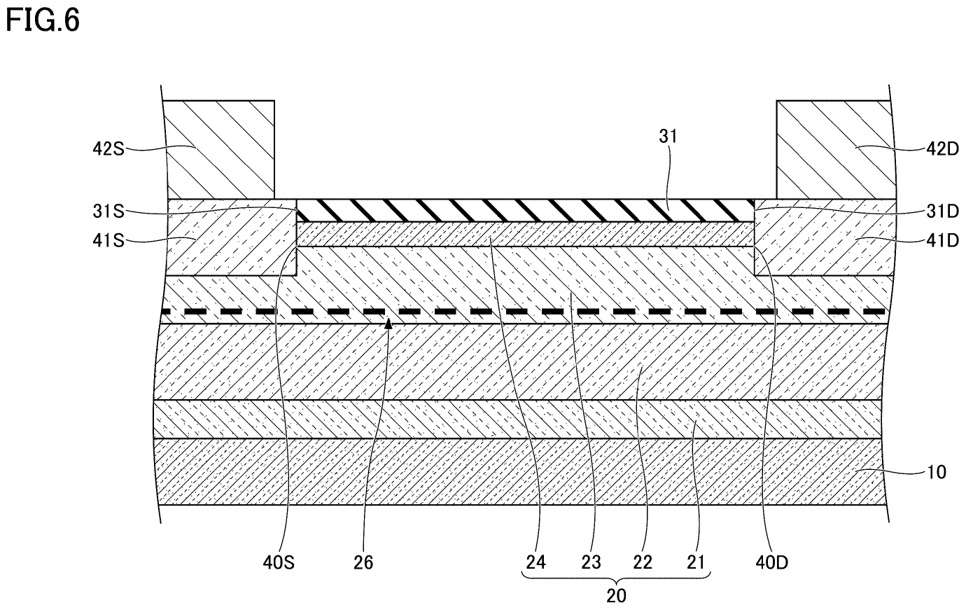

Next, as illustrated in FIG. 6, the source electrode 42S is formed on the regrowth layer 41S, and the drain electrode 42D is formed on the regrowth layer 41D. When forming the source electrode 42S and the drain electrode 42D, a metallic layer (not illustrated) constituting the source electrode 42S and the drain electrode 42D is first formed. When forming the metal layer, a film forming process (or deposition) is performed using a growth mask (not illustrated) having an opening in a region where the metal layer is to be formed, for example, and the growth mask is thereafter removed together with the metal layer (not illustrated) formed thereon. That is, a lift-off is performed.

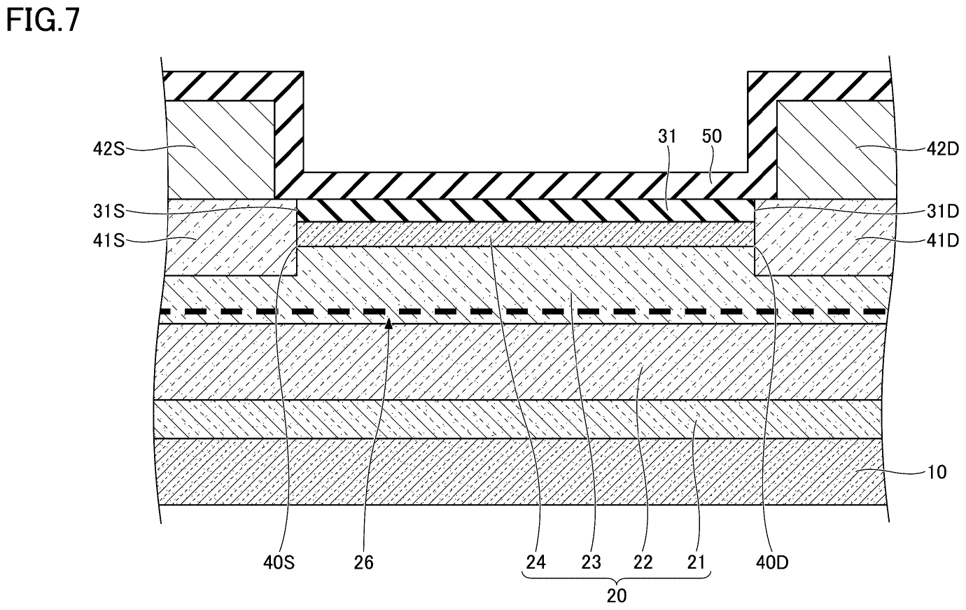

Next, as illustrated in FIG. 7, the passivation film 50 is formed on the dielectric film 31, the regrowth layer 41S, the regrowth layer 41D, the source electrode 42S, and the drain electrode 42D. The passivation film 50 covers the dielectric film 31, the regrowth layer 41S, the regrowth layer 41D, the source electrode 42S, and the drain electrode 42D.

Next, the opening 50G for the gate is formed in the passivation film 50 (refer to FIG. 1). The opening 50G can be formed by RIE using a mask (not illustrated), for example.

Next, the gate electrode 43 in contact with the dielectric film 31 through the openings 50G is formed on the passivation film 50 and the dielectric film 31 (refer to FIG. 1). When forming the gate electrode 43, a metal layer is formed using a growth mask (not illustrated) having an opening in a region where the gate electrode 43 is to be formed, for example, and the growth mask is thereafter removed together with the metal layer (not illustrated) formed thereon. That is, a lift-off is performed.

Next, the opening 50S for the source and the opening 50D for the drain are formed in the passivation film 50 (refer to FIG. 1). The opening 50S and the opening 50D can be formed by RIE using a mask (not illustrated), for example.

The semiconductor device 1 can be manufactured by the processes described above.

In the semiconductor device 1 according to the embodiment, because the buffer layer 21 includes Fe as a dopant, the buffer layer 21 can be made to have a high resistance, thereby enabling a high output and high frequency characteristics to be easily obtained. Further, because the upper surface 21A of the buffer layer 21, the upper surface 22A of the barrier layer 22 and the upper surface 23A of the channel layer 23 have the N polarity, diffusion of Fe atoms from the buffer layer 21 to the channel layer 23 and a decrease in an electron mobility caused by the Fe atoms in the channel layer 23 are less likely to occur compared to a case where the upper surfaces 21A, 22A, and 23A have a Ga polarity. Accordingly, by reducing a distance (or a length) L1 between the upper surface 21A of the buffer layer 21 and the lower surface 23B of the channel layer 23, it is possible to improve the heat dissipation (thermal conduction) from the channel layer 23 to the substrate 10, while obtaining a high electron mobility in the channel region 26.

In addition, because the upper surface 22A of the barrier layer 22 and the upper surface 23A of the channel layer 23 have the N polarity, a distance between the channel region 26 and the source electrode 42S and a distance between the channel region 26 and the drain electrode 42D can easily be reduced. Thus, the resistance between the channel region 26 and the source electrode 42S and the resistance between the channel region 26 and the drain electrode 42D can easily be reduced.

The barrier layer 22 has a thickness greater than or equal to 1 nm and less than or equal to 50 nm, for example. If the barrier layer 22 is thinner than 1 nm, a concentration of the 2DEG may become too low, to deteriorate the electron mobility, or increase the Fe atoms diffused from the buffer layer 21 to the channel layer 23. On the other hand, it the barrier layer 22 is thicker than the 50 nm, the thermal conduction from the channel layer 23 to the substrate 10 may deteriorate. The thickness of the barrier layer 22 may be greater than or equal to 5 nm and less than or equal to 40 nm, or may be greater than or equal to 10 nm and less than or equal to 30 nm. In the present embodiment, the thickness of the barrier layer 22 is equal to the distance L1.

An average value of the concentration of the Fe atoms in the channel layer 23 is 2×10¹⁶ cm⁻³ or lower, for example. When the average value of the concentration of the Fe atoms in the channel layer 23 is 2×10¹⁶ cm⁻³ or lower, a high electron mobility can be obtained in the channel region 26. The average value of the concentration of the Fe atoms in the channel layer 23 may be 1.5×10¹⁶ cm⁻³ or lower, or may be 1×10¹⁶ cm⁻³ or lower, for example. The characteristics do not deteriorate due to an excessively low concentration of the Fe atoms in the channel layer 23.

The average value of the concentration of the Fe atoms in the buffer layer 21 is 5×10¹⁷ cm⁻³ or higher, for example. When the average value of the concentration of the Fe atoms in the buffer layer 21 is 5×10¹⁷ cm⁻³ or higher, the buffer layer 21 can have a high resistance. The average value of the concentration of the Fe atoms in the buffer layer 21 may be 7×10¹⁷ cm⁻³ or higher, or may be 1×10¹⁸ cm⁻³ or higher. The average value of the concentration of the Fe atoms in the buffer layer 21 is 1×10²⁰ cm⁻³ or lower, for example. If the average value of the concentration of the Fe atoms in the buffer layer 21 is higher than 1×10²⁰ cm⁻³, the crystallinity of the buffer layer 21 deteriorates, and the crystallinity of the barrier layer 22, the channel layer 23, and the cap layer 24 may also deteriorate. Further, an attempt is made to form the buffer layer 21 having the average value of the concentration of the Fe atoms higher than 1×10²⁰ cm⁻³, Fe deposition may occur, and the barrier layer 22 and the channel layer 23 may grown abnormally thereon. For example, the buffer layer 21 has a resistivity of 1 MΩ·m or higher.

The concentration of the Fe atoms in the buffer layer 21 and the concentration of the Fe atoms in the channel layer 23 can be measured by secondary ion mass spectrometry (SIMS).

In addition, in a case where the buffer layer 21 is a GaN layer, the barrier layer 22 is an AlGaN layer, and the channel layer 23 is a GaN layer, it is possible to stably form the buffer layer 21, the barrier layer 22, and the channel layer 23 with ease.

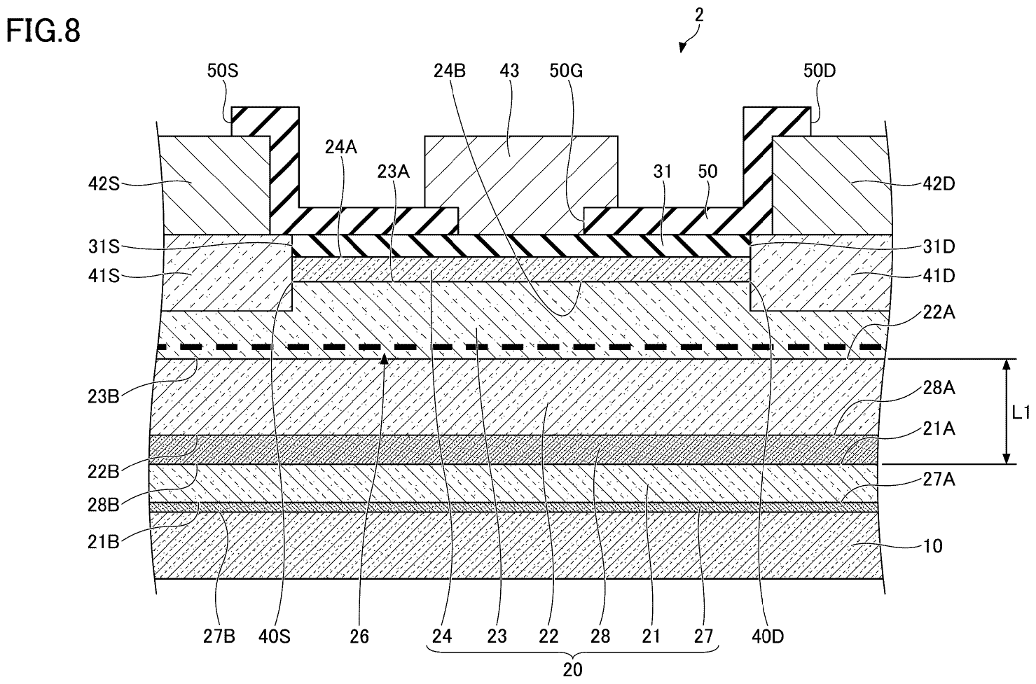

Next, a modification of the embodiment will be described. The modification differs from the embodiment described above, mainly in the configuration of the nitride semiconductor layer 20. FIG. 8 is a cross sectional view illustrating the semiconductor device according to the modification of the embodiment.

As illustrated in FIG. 8, in a semiconductor device 2 according to the modification of the embodiment, the nitride semiconductor layer 20 includes a nucleation layer 27 and a second buffer layer 28, in addition to the buffer layer 21, the barrier layer 22, the channel layer 23, and the cap layer 24.

The nucleation layer 27 is provided between the substrate 10 and the buffer layer 21. The nucleation layer 27 is an AlN layer, for example. An upper surface 27A of the nucleation layer 27 has a N polarity, and a lower surface 27B of the nucleation layer 27 has an Al polarity. The nucleation layer 27 functions as a nucleus of the growth of the nitride semiconductor layer 20.

The second buffer layer 28 is provided between the buffer layer 21 and the barrier layer 22. The second buffer layer 28 is a GaN layer, for example, and a conductivity type of the second buffer layer 28 is undoped (i-type). An upper surface 28A of the second buffer layer 28 has a N polarity, and a lower surface 28B of the second buffer layer 28 has a Ga polarity. The provision of the second buffer layer 28 makes it difficult for the Fe atoms to diffuse from the buffer layer 21 to the channel layer 23. Accordingly, an average value of the concentration of the Fe atoms in the channel layer 23 of the modification is smaller than an average value of the concentration of the Fe atoms in the channel layer 23 of the embodiment. Further, an average value of the concentration of the Fe atoms in the channel layer 23 is smaller than an average value of the concentration of the Fe atoms in the barrier layer 22, and the average value of the concentration of the Fe atoms in the barrier layer 22 is smaller than an average value of the concentration of the Fe atoms in the second barrier layer 28, and the average value of the concentration of the Fe atoms in the second barrier layer 28 is smaller than an average value of the concentration of the Fe atoms in the buffer layer 21.

Otherwise, the configuration of the semiconductor device 2 is the same as that of the semiconductor device 1. The semiconductor device 2 can also obtain effects or advantageous features that are the same as those obtainable by the semiconductor device 1.

The distance L1 is greater than or equal to 1 nm and less than or equal to 50 nm, for example. If the distance L1 is less than 1 nm, the barrier layer 22 becomes thin, thereby causing lowering of the concentration of the 2DEG, lowering of the electron mobility, and easy diffusion of the Fe atoms from the buffer layer 21 to the channel layer 23. If the distance L1 is greater than 50 nm, the heat dissipation from the channel layer 23 to the substrate 10 may deteriorate. The distance L1 may be greater than or equal to 5 nm and less than or equal to 40 nm, or may be greater than or equal to 10 nm and less than or equal to 30 nm.

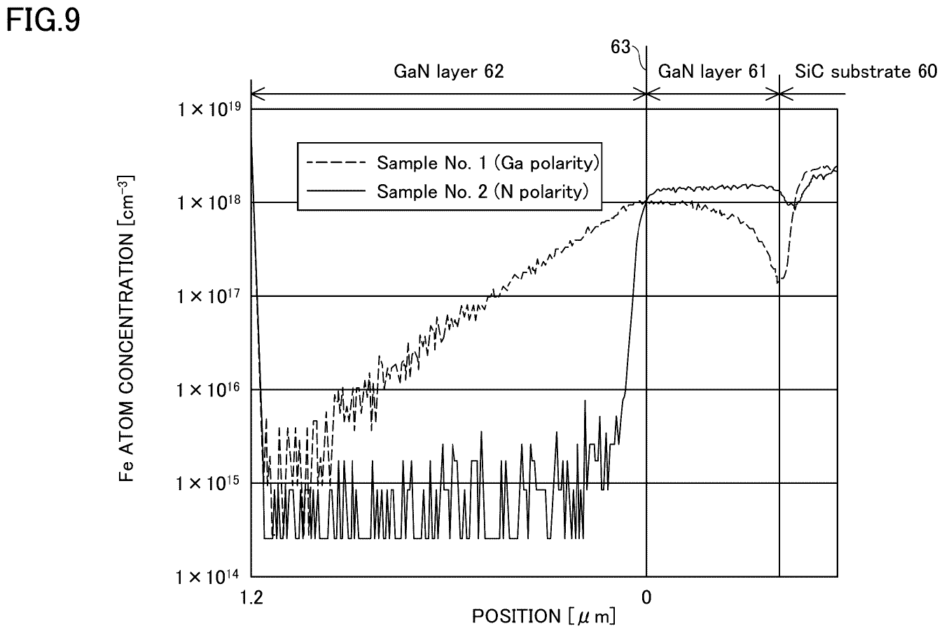

Next, experiments conducted by the present inventor will be described. In the experiments, SiC substrates 60 having upper surfaces with a C polarity or Si polarity were prepared, respectively, a GaN layer 61 including Fe was formed on each of the SiC substrates 60, and a GaN layer 62 not intentionally doped with Fe atoms was formed on the GaN layer 61. When forming the GaN layer 61, the GaN layer 61 was doped with Fe atoms so that an average value of the concentration becomes 1×10¹⁸ cm⁻³, and the GaN layer 61 was formed to a thickness of 500 nm. The GaN layer 62 was formed to a thickness of 1200 nm. Then, the concentration of the Fe atoms in each sample was measured by SIMS. Measurement results are illustrated in FIG. 9. In FIG. 9, the ordinate indicates the concentration of the Fe atoms (that is, the Fe atom concentration), and the abscissa indicates the position. In a sample No. 1 using the SiC substrate 60 having the upper surface with the Si polarity, the polarity of the upper surfaces of the GaN layer 61 and the GaN layer 62 is the Ga polarity. In a sample No. 2 using the SiC substrate 60 having the upper surface with the C polarity, the polarity of the upper surfaces of the GaN layer 61 and the GaN layer 62 is the N polarity.

As illustrated in FIG. 9, the concentration of the Fe atoms in the GaN layer 62 decreases with an increase of distance from an interface 63 between the GaN layer 61 and the GaN layer 62. However, in the sample No. 1, the concentration of the Fe atoms in the GaN layer 62 decreases to 1×10¹⁶ cm⁻³ at a position separated from the interface 63 by a distance greater than or equal to 800 nm. This indicates that, in a case where the GaN layer 61 is used as the buffer layer and the GaN layer 62 is used as the channel layer with the same polarity as that of the sample No. 1, the channel region needs to be separated from the buffer layer including Fe by a distance greater than or equal to 800 nm in order to set the concentration of the Fe atoms in the channel region to 1×10¹⁶ cm⁻³ or lower. On the other hand, in the sample No. 2, the concentration of the Fe atoms in the GaN layer 62 decreases to 1×10¹⁶ cm⁻³ at a position separated from the interface 63 by a distance of approximately 50 nm. This indicates that, in the case where the GaN layer 61 is used as the buffer layer and the GaN layer 62 is used as the channel layer with the same polarity as that of the sample No. 2, the channel region needs to be separated from the buffer layer including Fe by a distance of approximately 50 nm in order to set the concentration of the Fe atoms in the channel region to 1×10¹⁶ cm⁻³ or lower. Hence, according to the sample No. 2, it is possible to greatly reduce the distance between the buffer layer including Fe and the channel region, and to greatly reduce a thermal resistance, when compared to the sample No. 1.

According to the present disclosure, it is possible to improve heat dissipation of the semiconductor device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a buffer layer including iron atoms and having a nitrogen polarity at an upper surface thereof;
a barrier layer provided on the buffer layer and having a nitrogen polarity at an upper surface thereof; and
a channel layer provided on the barrier layer and having a nitrogen polarity at an upper surface thereof.

2. The semiconductor device as claimed in claim 1, wherein the barrier layer has a thickness greater than or equal to 1 nm and smaller than or equal to 50 nm.

3. The semiconductor device as claimed in claim 1, wherein a separation between the upper surface of the buffer layer and a lower surface of the channel layer is greater than or equal to 1 nm and less than or equal to 50 nm.

4. The semiconductor device as claimed in claim 1, wherein the channel layer has an average value of a concentration of iron atoms which is 2×10¹⁶ cm⁻³ or lower.

5. The semiconductor device as claimed in claim 1, wherein the buffer layer has an average value of a concentration of the iron atoms which is 5×10¹⁷ cm⁻³ or higher.

6. The semiconductor device as claimed in claim 1, wherein:
the barrier layer has a thickness greater than or equal to 1 nm and less than or equal to 50 nm,
the channel layer has an average value of a concentration of iron atoms which is 2×10¹⁶ cm⁻³ or lower, and
the buffer layer has an average value of a concentration of iron atoms which is 5×10¹⁷ cm⁻³ or higher.

7. The semiconductor device as claimed in claim 1, wherein:
the buffer layer is a gallium nitride layer,
the barrier layer is an aluminum gallium nitride layer, and
the channel layer is a gallium nitride layer.

8. The semiconductor device as claimed in claim 2, wherein:
the buffer layer is a gallium nitride layer,
the barrier layer is an aluminum gallium nitride layer, and
the channel layer is a gallium nitride layer.

9. The semiconductor device as claimed in claim 3, wherein:
the buffer layer is a gallium nitride layer,
the barrier layer is an aluminum gallium nitride layer, and
the channel layer is a gallium nitride layer.

10. The semiconductor device as claimed in claim 6, wherein:
the buffer layer is a gallium nitride layer,
the barrier layer is an aluminum gallium nitride layer, and
the channel layer is a gallium nitride layer.
